(19) United States
(12) Patent Application Publication
(10) Pub. No.: US 2022/0180931 A1
(43) Pub. Date: Jun. 9, 2022

(54) SEMICONDUCTOR MEMORY DEVICE AND METHOD OF OPERATING THE SAME

(71) Applicant: SK hynix Inc., Gyeonggi-do (KR)

(72) Inventors: Sung Bak KIM, Gyeonggi-do (KR); Kyu Nam LIM, Gyeonggi-do (KR); Se Chun PARK, Gyeonggi-do (KR)

(21) Appl. No.: 17/350,637

(22) Filed: Jun. 17, 2021

(30) Foreign Application Priority Data
Dec. 8, 2020 (KR) 10-2020-0170531

(51) Int. Cl. G11C 16/10; G11C 11/56; G11C 16/04; G11C 16/24; G11C 16/34

(52) U.S. Cl. CPC G11C 16/10; G11C 11/5628; G11C 16/3459; G11C 16/0483; G11C 16/24; G11C 11/5671

(57) ABSTRACT

The present technology relates to a semiconductor memory device and a method of operating the same. The semiconductor memory device includes a memory cell array including a plurality of memory blocks, peripheral circuits for performing a program operation on a selected memory block among the plurality of memory blocks, and a control logic for controlling the peripheral circuits to perform a detrap operation between a program voltage apply operation and a program verify operation during the program operation, and the peripheral circuits apply a positive set voltage to a source line connected to the selected memory block during the detrap operation.

### CROSS-REFERENCE TO RELATED APPLICATION

The present application claims priority under 35 U.S.C. § 119(a) to Korean patent application number 10-2020-0170531 filed on Dec. 8, 2020, which is incorporated herein by reference in its entirety.

### BACKGROUND

### Field of Invention

The present application relates to an electronic device, and more particularly, to a semiconductor memory device and a method of operating the same.

### Description of Related Art

A semiconductor memory device is a memory device that is implemented using a semiconductor such as silicon (Si), germanium (Ge), gallium arsenide (GaAs), or indium phosphide (InP). The semiconductor memory device is largely classified into a volatile memory device and a nonvolatile memory device.

The volatile memory device is a memory device in which stored data is lost when its power supply is cut off. The volatile memory device includes a static RAM (SRAM), a dynamic RAM (DRAM), a synchronous DRAM (SDRAM), and the like. The nonvolatile memory device is a memory device that maintains stored data even though its power supply is cut off. The nonvolatile memory device includes a read only memory (ROM), a programmable ROM (PROM), an electrically programmable ROM (EPROM), an electrically erasable and programmable ROM (EEPROM), a flash memory, a phase-change RAM (PRAM), a magnetic RAM (MRAM), a resistive RAM (RRAM), a ferroelectric RAM (FRAM), and the like. The flash memory is largely classified into a NOR type and a NAND type.

### SUMMARY

An embodiment of the present disclosure provides a semiconductor memory device capable of improving a threshold voltage distribution of memory cells during a program operation, and a method of operating the same.

According to an embodiment of the present disclosure, a semiconductor memory device includes a memory cell array including a plurality of memory blocks, peripheral circuits for performing a program operation on a selected memory block among the plurality of memory blocks, and a control logic for controlling the peripheral circuits to perform a detrap operation between a program voltage apply operation and a program verify operation during the program operation, and the peripheral circuits apply a positive set voltage to a source line connected to the selected memory block during the detrap operation.

According to an embodiment of the present disclosure, a semiconductor memory device includes a memory block including memory cells to be programmed to a plurality of program states, peripheral circuits for performing a program operation on the memory block, and a control logic for controlling the peripheral circuits to perform the program operation, and the control logic controls the peripheral circuits to sequentially perform a program voltage apply operation, a detrap operation, and a program verify operation during the program operation on some of the plurality of program states.

According to an embodiment of the present disclosure, a method of operating a semiconductor memory device includes performing a program voltage apply operation of applying a program voltage to a selected word line among a plurality of word lines connected to a cell string including a plurality of memory cells programmed to a plurality of program states, performing a detrap operation of applying a positive set voltage to a source line connected to the cell string after performing the program voltage apply operation, and performing a program verify operation of applying a program verify voltage to the selected word line and sensing a voltage or a current of a bit line connected to the cell string, after performing the detrap operation.

The present technology may improve a retention deterioration characteristic during a program operation of a semiconductor memory device, thereby improving a phenomenon in which a threshold voltage distribution of memory cells is changed.

According to an embodiment of the present disclosure, a programming method of a nonvolatile memory device, the programming method comprising at least one program loop includes programming a cell capable of storing information of two or more bits, detrapping charges from the cell by raising a channel voltage of a cell string including the cell, and verifying the programming.

### BRIEF DESCRIPTION OF THE DRAWINGS

FIG. 1 is a diagram illustrating a semiconductor memory device according to an embodiment of the present disclosure.

FIG. 2 is a diagram illustrating a memory cell array of FIG. 1 according to an embodiment of the present disclosure.

FIG. 3 is a circuit diagram illustrating a memory block BLK1 of memory blocks BLK1 to BLKz of FIG. 2 according to an embodiment of the present disclosure.

FIG. 4 is a circuit diagram illustrating a memory block BLK2 of the memory blocks BLK1 to BLKz of FIG. 2 according to an embodiment of the present disclosure.

FIG. 5 is a circuit diagram illustrating a memory block BLK3 of the memory blocks BLK1 to BLKz included in the memory cell array 110 of FIG. 1 according to an embodiment of the present disclosure.

FIG. 6 is a graph illustrating program states of a triple-level cell according to an embodiment of the present disclosure.

FIG. 7 is a diagram illustrating a program operation according to an embodiment of the present disclosure.

FIGS. 8 and 9 are flowcharts illustrating a program operation according to an embodiment of the present disclosure.

FIG. 10 is a diagram illustrating one program loop among the plurality of program loops of FIG. 7 according to an embodiment of the present disclosure.

FIG. 11 is a block diagram illustrating a memory system 1000 including the semiconductor memory device of FIG. 1 according to an embodiment of the present disclosure.

FIG. 12 is a block diagram illustrating an application example of the memory system of FIG. 11 according to an embodiment of the present disclosure.

FIG. 13 is a block diagram illustrating a computing system including the memory system described with reference to FIG. 12 according to an embodiment of the present disclosure.

### DETAILED DESCRIPTION

Specific structural or functional descriptions of embodiments according to the concept which are disclosed in the present specification or application are illustrated only to describe the embodiments according to the concept of the present disclosure. The embodiments according to the concept of the present disclosure may be carried out in various forms and are not limited to the embodiments described in the present specification or application.

Hereinafter, an embodiment of the present disclosure is described in detail with reference to the accompanying drawings, so that those skilled in the art to which the present disclosure pertains may easily carry out the technical spirit of the present disclosure.

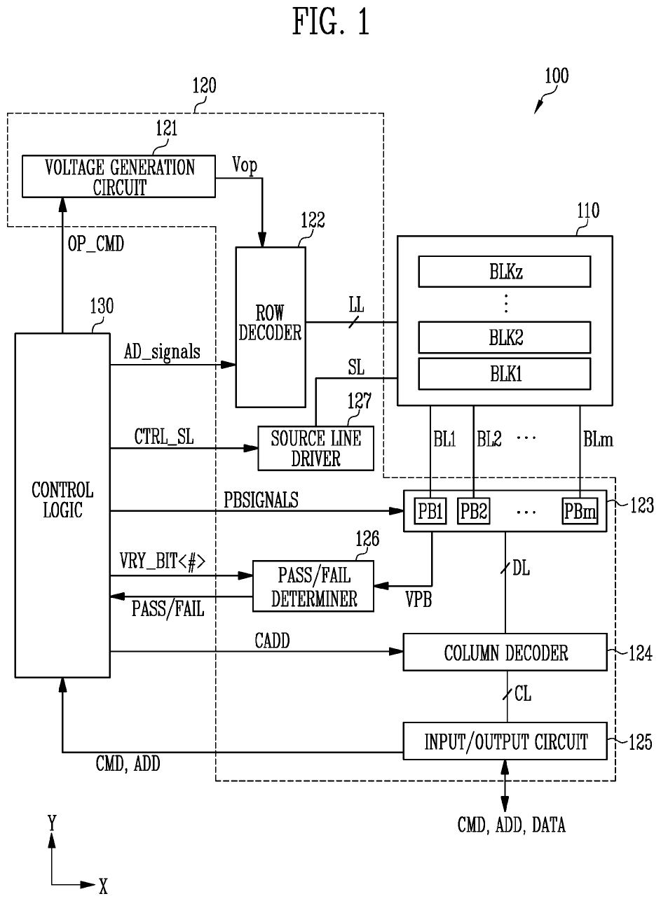

FIG. 1 is a diagram illustrating a semiconductor memory device according to an embodiment of the present disclosure.

Referring to FIG. 1, the semiconductor memory device 100 may include a memory cell array 110 in which data is stored. The semiconductor memory device 100 may include peripheral circuits 120 configured to perform a program operation for storing the data in the memory cell array 110, a read operation for outputting the stored data, and an erase operation for erasing the stored data. The semiconductor memory device 100 may include a control logic 130 that controls the peripheral circuits 120.

The memory cell array 110 may include a plurality of memory blocks BLK1 to BLKz. Local lines LL and bit lines BL1 to BLm (m is a positive integer) may be connected to each of the memory blocks BLK1 to BLKz. For example, the local lines LL may include a first select line, a second select line, and a plurality of word lines arranged between the first and second select lines. In addition, the local lines LL may include dummy lines arranged between the first select line and the word lines, and between the second select line and the word lines. Here, the first select line may be a source select line, and the second select line may be a drain select line. For example, the local lines LL may include the word lines, the drain and source select lines, and source lines SL. For example, the local lines LL may further include dummy lines. For example, the local lines LL may further include pipe lines. The local lines LL may be connected to the memory blocks BLK1 to BLKz, respectively, and the bit lines BL1 to BLM may be commonly connected to the memory blocks BLK1 to BLKz. The memory blocks BLK1 to BLKz may be implemented in a two-dimensional or three-dimensional structure. For example, in the memory blocks BLK1 to BLKz of the two-dimensional structure, memory cells may be arranged in a direction parallel to the substrate. For example, in the memory blocks BLK1 to BLKz of the three-dimensional structure, memory cells may be stacked on a substrate in a vertical direction.

The peripheral circuits 120 may be configured to perform the program, read, and erase operations of a selected memory block under control of the control logic 130.

For example, the peripheral circuits 120 may include a voltage generation circuit 121, a row decoder 122, a page buffer group 123, a column decoder 124, an input/output circuit 125, a pass/fail determiner (a pass/fail check circuit) 126, and a source line driver 127.

The voltage generation circuit 121 may generate various operation voltages Vop used for the program, read, and erase operations in response to an operation signal OP_CMD. In addition, the voltage generation circuit 121 may selectively discharge the local lines LL in response to the operation signal OP_CMD. For example, the voltage generation circuit 121 may generate a program voltage, a verify voltage, and a pass voltage under control of the control logic 130.

The row decoder 122 may transfer the operation voltages Vop to the local lines LL connected to the selected memory block in response to row decoder control signals AD_signals. For example, during the program operation, the row decoder 122 may apply the program voltage generated by the voltage generation circuit 121 to a selected word line among selected local lines LL of the selected memory block in response to the row decoder control signals AD_signals, and may apply the pass voltage generated by the voltage generation circuit 121 to unselected word lines.

The page buffer group 123 may include a plurality of page buffers PB1 to PBm connected to the bit lines BL1 to BLm. The page buffers PB1 to PBm may operate in response to page buffer control signals PBSIGNALS. For example, the page buffers PB1 to PBm temporarily store data to be programmed during the program operation and adjust a potential level of the bit lines BL1 to BLm based on the temporarily stored data to be programmed. In addition, the page buffers PB1 to PBm may sense a voltage or a current of the bit lines BL1 to BLm during the read or program verify operation.

The column decoder 124 may transfer data between the input/output circuit 125 and the page buffer group 123 in response to a column address CADD. For example, the column decoder 124 may exchange data with the page buffers PB1 to PBm through the data lines DL, or exchange data with the input/output circuit 125 through column lines CL.

The input/output circuit 125 may transfer a command CMD and an address ADD received from the outside to the control logic 130 or may exchange data DATA with the column decoder 124.

During the read operation or the program verify operation, the pass/fail determiner 126 may generate a reference current in response to a permission bit VRY_BIT<#>, compare a sensing voltage VPB received from the page buffer group 123 with a reference voltage generated by the reference current, and output a pass signal PASS or a fail signal FAIL. The sensing voltage VPB may be a voltage controlled based on the number of memory cells determined as a pass during the program verify operation.

The source line driver 127 may be connected to a memory cell included in the memory cell array 110 through the source line SL, and may control a voltage applied to the source line SL. The source line driver 127 may receive a source line control signal CTRL_SL from the control logic 130 and control the voltage applied to the source line SL based on the source line control signal CTRL_SL.

The source line driver 127 may apply a positive set voltage to the source line SL during the program operation. For example, the source line driver 127 may apply the positive set voltage to the source line SL during a detrap operation of the program operation. The detrap operation may be performed after the program voltage apply operation is completed and before the program verify operation is performed. That is, the program operation may include the program voltage apply operation, the detrap operation, and the program verify operation which are sequentially performed.

During the program operation of the memory cells, charges may be trapped in a charge storage layer of the memory cells, and some of the trapped charges may be trapped in an unstable state. The charges trapped in the unstable state may be detrapped from the charge storage layer within a predetermined time after the program operation is completed, and thus, a threshold voltage of the memory cells may be lowered. In the present disclosure, after performing the program voltage apply operation, the program verify operation is performed after performing a detrap operation of detrapping the charges trapped in the unstable state in the charge storage layer of the selected memory cells by increasing a channel potential level of the selected memory block. Therefore, a phenomenon in which a retention characteristic and a threshold voltage distribution of the memory cells are changed may be improved.

In response to the command CMD and the address ADD, the control logic 130 may control the peripheral circuit 120 by outputting the operation signal OP_CMD, the row decoder control signals AD_signals, the page buffer control signals PBSIGNALS, and the permission bit VRY_BIT<#>. The control logic 130 may control the peripheral circuits 120 to sequentially perform the program voltage apply operation, the detrap operation, and the program verify operation during a program operation on the selected page of the selected memory block. The control logic 130 may control the source line driver 127 to apply the positive set voltage to the source line SL during the detrap operation.

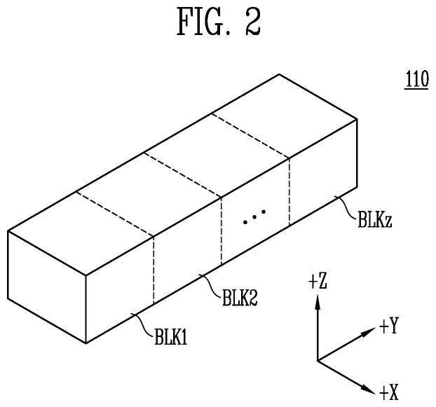

FIG. 2 is a diagram illustrating the memory cell array of FIG. 1 according to an embodiment of the present disclosure.

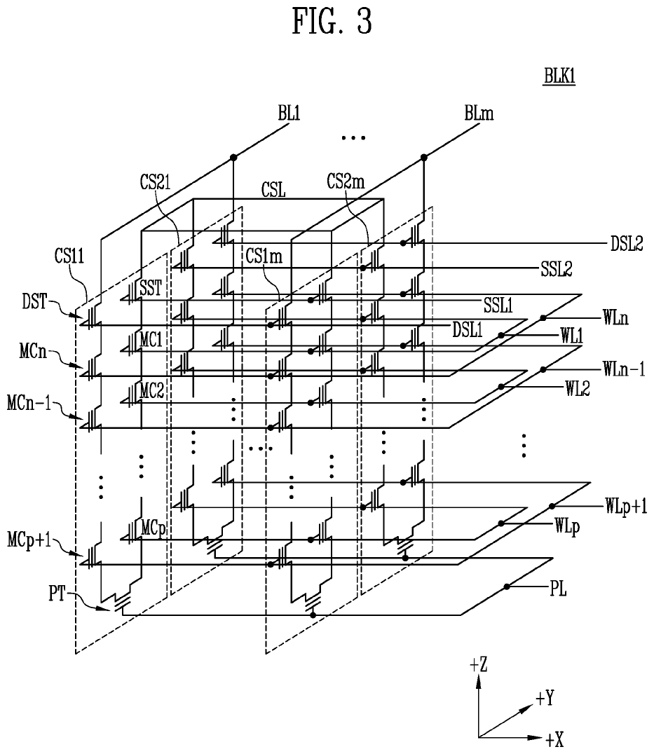

Referring to FIG. 2, the memory cell array 110 includes a plurality of memory blocks BLK1 to BLKz. Each memory block may have a three-dimensional structure. Each memory block includes a plurality of memory cells stacked on a substrate. Such plurality of memory cells are arranged along a +X direction, a +Y direction, and a +Z direction. A structure of each memory block is described in more detail with reference to FIGS. 3 to 5.

FIG. 3 is a circuit diagram illustrating a memory block BLK1 of the memory blocks BLK1 to BLKz of FIG. 2 according to an embodiment of the present disclosure.

Referring to FIG. 3, the memory block BLK1 includes a plurality of cell strings CS11 to CS1m and CS21 to CS2m. In an embodiment, each of the plurality of cell strings CS11 to CS1m and CS21 to CS2m may be formed in a ‘U’ shape. In the memory block BLK1, m cell strings are arranged in a row direction (that is, the +X direction). In FIG. 3, two cell strings are arranged in a column direction (that is, the +Y direction). However, this is for convenience of description and it may be understood that three or more cell strings may be arranged in the column direction.

Each of the plurality of cell strings CS11 to CS1m and CS21 to CS2m includes at least one source select transistor SST, first to n-th memory cells MC1 to MCn, a pipe transistor PT, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating film, a charge storage film, and a blocking insulating film. In an embodiment, a pillar for providing the channel layer may be provided in each cell string. In an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCp.

In an embodiment, the source select transistors of the cell strings arranged in the same row are connected to a source select line extending in the row direction, and the source select transistors of the cell strings arranged in different rows are connected to different source select lines. In FIG. 3, the source select transistors of the cell strings CS11 to CS1m of a first row are connected to a first source select line SSL1. The source select transistors of the cell strings CS21 to CS2m of a second row are connected to a second source select line SSL2.

In another embodiment, the source select transistors of the cell strings CS11 to CS1m and CS21 to CS2m may be commonly connected to one source select line.

The first to n-th memory cells MC1 to MCn of each cell string are connected between the source select transistor SST and the drain select transistor DST.

The first to n-th memory cells MC1 to MCn may be divided into first to p-th memory cells MC1 to MCp and (p+1)-th to n-th memory cells MCp+1 to MCn. The first to p-th memory cells MC1 to MCp are sequentially arranged in a direction opposite to the +Z direction, and are connected in series between the source select transistor SST and the pipe transistor PT. The (p+1)-th to n-th memory cells MCp+1 to MCn are sequentially arranged in the +Z direction, and are connected in series between the pipe transistor PT and the drain select transistor DST. The first to p-th memory cells MC1 to MCp and the (p+1)-th to n-th memory cells MCp+1 to MCn are connected to each other through the pipe transistor PT. Gates of the first to n-th memory cells MC1 to MCn of each cell string are connected to the first to n-th word lines WL1 to WLn, respectively.

A gate of the pipe transistor PT of each cell string is connected to a pipeline PL.

The drain select transistor DST of each cell string is connected between a corresponding bit line and the memory cells MCp+1 to MCn. The cell strings arranged in the row direction are connected to the drain select line extending in the row direction. The drain select transistors of the cell strings CS11 to CS1m of the first row are connected to a first drain select line DSL1. The drain select transistors of the cell strings CS21 to CS2m of the second row are connected to a second drain select line DSL2.

The cell strings arranged in the column direction are connected to the bit lines extending in the column direction. In FIG. 3, the cell strings CS11 and CS21 of the first column are connected to the first bit line BL1. The cell strings CS1m and CS2m of the m-th column are connected to the m-th bit line BLm.

The memory cells connected to the same word line in the cell strings arranged in the row direction configure one page. For example, the memory cells connected to the first word line WL1, among the cell strings CS11 to CS1m of the first row configure one page. The memory cells connected to the first word line WL1, among the cell strings CS21 to CS2m of the second row configure another page. The cell strings arranged in one row direction may be selected by selecting any of the drain select lines DSL1 and DSL2. One page of the selected cell strings may be selected by selecting any of the word lines WL1 to WLn.

In another embodiment, even bit lines and odd bit lines may be provided instead of the first to m-th bit lines BL1 to BLm. In addition, even-numbered cell strings among the cell strings CS11 to CS1m or CS21 to SC2m arranged in the row direction may be connected to the bit lines, and odd-numbered cell strings among the cell strings CS11 to CS1m or CS21 to CS2m arranged in the row direction may be connected to odd bit lines, respectively.

In an embodiment, at least one of the first to n-th memory cells MC1 to MCn may be used as a dummy memory cell. For example, at least one dummy memory cell is provided to reduce an electric field between the source select transistor SST and the memory cells MC1 to MCp. Alternatively, at least one dummy memory cell is provided to reduce an electric field between the drain select transistor DST and the memory cells MCp+1 to MCn. As more dummy memory cells are provided, reliability of an operation for the memory block BLK1 is improved, however, the size of the memory block BLK1 increases. As less memory cells are provided, the size of the memory block BLK1 may be reduced, however, the reliability of the operation for the memory block BLK1 may be reduced.

In order to efficiently control at least one dummy memory cell, each of the dummy memory cells may have a required threshold voltage. Before or after an erase operation for the memory block BLK1, program operations for all or a part of the dummy memory cells may be performed. When the erase operation is performed after the program operation is performed, the dummy memory cells may have the required threshold voltage by controlling a voltage applied to dummy word lines connected to the respective dummy memory cells.

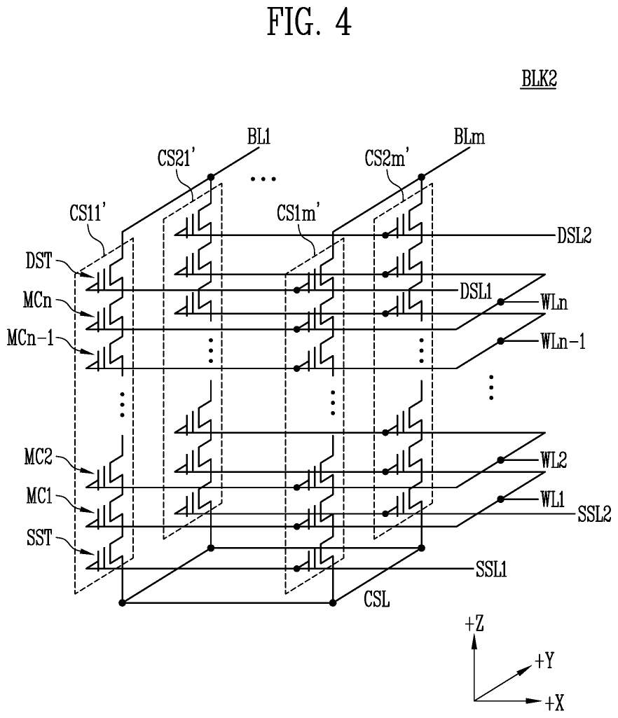

FIG. 4 is a circuit diagram illustrating a memory block BLK2 of the memory blocks BLK1 to BLKz of FIG. 2 according to an embodiment of the present disclosure.

Referring to FIG. 4, the memory block BLK2 includes a plurality of cell strings CS11′ to CS1m′ and CS21′ to CS2m′. Each of the plurality of cell strings CS11′ to CS1m′ and CS21′ to CS2m′ extends along a +Z direction. Each of the plurality of cell strings CS11′ to CS1m′ and CS21′ to CS2m′ includes at least one source select transistor SST, first to n-th memory cells MC1 to MCn, and at least one drain select transistor DST stacked on a substrate (not shown) under the memory block BLK2.

The source select transistor SST of each cell string is connected between a common source line CSL and memory cells MC1 to MCn. The source select transistors of the cell strings arranged in the same row are connected to the same source select line. The source select transistors of the cell strings CS11′ to CS1m′ arranged in a first row are connected to a first source select line SSL1. The source select transistors of the cell strings CS21′ to CS2m′ arranged in a second row are connected to a second source select line SSL2. In another embodiment, the source select transistors of the cell strings CS11′ to CS1m′ and CS21′ to CS2m′ may be commonly connected to one source select line.

The first to n-th memory cells MC1 to MCn of each cell string are connected in series between the source select transistor SST and the drain select transistor DST. Gates of the first to n-th memory cells MC1 to MCn are connected to first to the n-th word lines WL1 to WLn, respectively.

The drain select transistor DST of each cell string is connected between a corresponding bit line and the memory cells MC1 to MCn. The drain select transistors of the cell strings arranged in the row direction are connected to a drain select line extending in the row direction. The drain select transistors of the cell strings CS11′ to CS1m′ of a first row are connected to a first drain select line DSL1. The drain select transistors of the cell strings CS21′ to CS2m′ of a second row are connected to a second drain select line DSL2.

As a result, the memory block BLK2 of FIG. 4 has an equivalent circuit similar to that of the memory block BLK1 of FIG. 3 except that the pipe transistor PT is excluded from each cell string.

In another embodiment, even bit lines and odd bit lines may be provided instead of the first to m-th bit lines BL1 to BLm. In addition, even-numbered cell strings among the cell strings CS11′ to CS1m′ or CS21′ to CS2m′ arranged in the row direction may be connected to even bit lines, and odd-numbered cell strings among the cell strings CS11′ to CS1m′ or CS21′ to CS2m′ arranged in the row direction may be connected to odd bit lines, respectively.

In an embodiment, at least one of the first to n-th memory cells MC1 to MCn may be used as a dummy memory cell. For example, at least one dummy memory cell is provided to reduce an electric field between the source select transistor SST and the memory cells MC1 to MCn. Alternatively, at least one dummy memory cell is provided to reduce an electric field between the drain select transistor DST and the memory cells MC1 to MCn. As more dummy memory cells are provided, reliability of an operation for the memory block BLK2 is improved, however, the size of the memory block BLK2 increases. As less memory cells are provided, the size of the memory block BLK2 may be reduced, however, the reliability of the operation for the memory block BLK2 may be reduced.

In order to efficiently control at least one dummy memory cell, each of the dummy memory cells may have a required threshold voltage. Before or after an erase operation for the memory block BLK2, program operations for all or a part of the dummy memory cells may be performed. When the erase operation is performed after the program operation is performed, the dummy memory cells may have the required threshold voltage by controlling a voltage applied to the dummy word lines connected to the respective dummy memory cells.

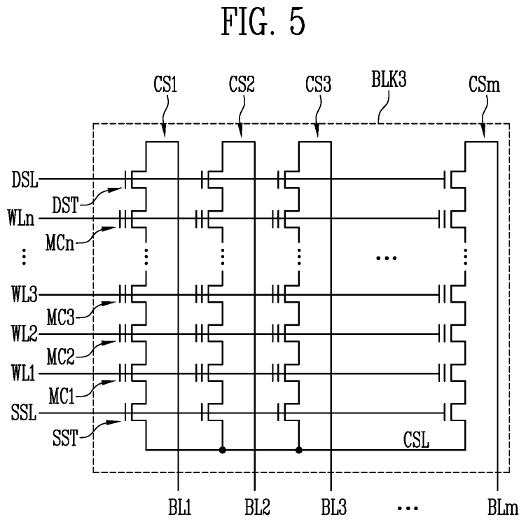

FIG. 5 is a circuit diagram illustrating a memory block BLK3 of the memory blocks BLK1 to BLKz included in the memory cell array 110 of FIG. 1 according to an embodiment of the present disclosure.

Referring to FIG. 5, the memory block BLK3 includes a plurality of cell strings CS1 to CSm. The plurality of cell strings CS1 to CSm may be connected to a plurality of bit lines BL1 to BLm, respectively. Each of the cell strings CS1 to CSm includes at least one source select transistor SST, first to n-th memory cells MC1 to MCn, and at least one drain select transistor DST.

Each of the select transistors SST and DST and the memory cells MC1 to MCn may have a similar structure. In an embodiment, each of the select transistors SST and DST and the memory cells MC1 to MCn may include a channel layer, a tunneling insulating film, a charge storage film, and a blocking insulating film. In an embodiment, a pillar for providing the channel layer may be provided in each cell string. In an embodiment, a pillar for providing at least one of the channel layer, the tunneling insulating film, the charge storage film, and the blocking insulating film may be provided in each cell string.

The source select transistor SST of each cell string is connected between a common source line CSL and the memory cells MC1 to MCn.

The first to n-th memory cells MC1 to MCn of each cell string are connected between the source select transistor SST and the drain select transistor DST.

The drain select transistor DST of each cell string is connected between a corresponding bit line and the memory cells MC1 to MCn.

Memory cells connected to the same word line configure one page. The cell strings CS1 to CSm may be selected by selecting the drain select line DSL. One page among the selected cell strings may be selected by selecting one of the word lines WL1 to WLn.

In another embodiment, even bit lines and odd bit lines may be provided instead of the first to m-th bit lines BL1 to BLm. Even-numbered cell strings among the cell strings CS1 to CSm may be connected to even bit lines, and odd-numbered cell strings may be connected to odd bit lines, respectively.

As described above, the memory cells connected to one word line may configure one physical page. In the example of FIG. 5, among the memory cells belonging to the memory block BLK3, m memory cells connected to one of the plurality of word lines WL1 to WLn configure one physical page.

As shown in FIGS. 3 and 4, the memory cell array 110 of the semiconductor memory device 100 may be configured in a three-dimensional structure, but as shown in FIG. 5, the memory cell array 110 may be configured in a two-dimensional structure.

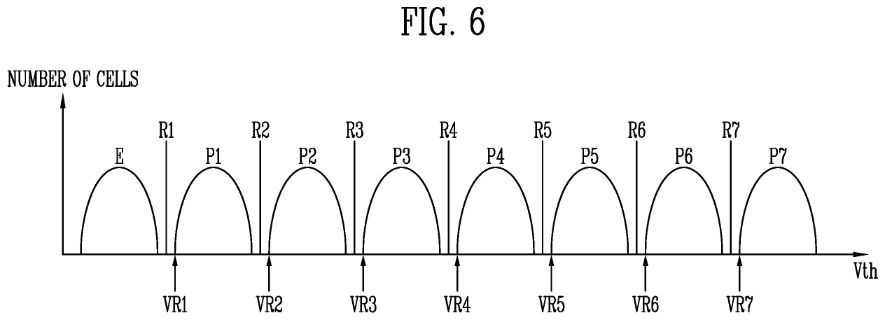

FIG. 6 is a graph illustrating program states of a triple-level cell according to an embodiment of the present disclosure.

Referring to FIG. 6, the triple-level cell (TLC) has threshold voltage states corresponding to one erase state E and seven program states P1 to P7, respectively. The erase state E and the first to seventh program states P1 to P7 have a corresponding bit code. Various bit codes may be assigned to the erase state E and the first to seventh program states P1 to P7 as needed.

Each of the threshold voltage states may be classified based on first to seventh read voltages R1 to R7. In addition, first to seventh verify voltages VR1 to VR7 may be used to determine whether a program of memory cells corresponding to each program state is completed.

For example, the second verify voltage VR2 is applied to the word line to verify memory cells corresponding to the second program state P2 among the memory cells included in the selected physical page. At this time, the page buffer PB1 shown in FIG. 1 may sense a current of the bit line BL1 to distinguish whether a target memory cell connected to the bit line BL1 is in a program incomplete state or a program complete state.

Although target program states of the TLC are shown in FIG. 6, the plurality of memory cells included in the semiconductor memory device according to an embodiment of the present disclosure may be a multi-level cell (MLC). In another embodiment, the plurality of memory cells included in the semiconductor memory device according to an embodiment of the present disclosure may be a quad-level cell (QLC).

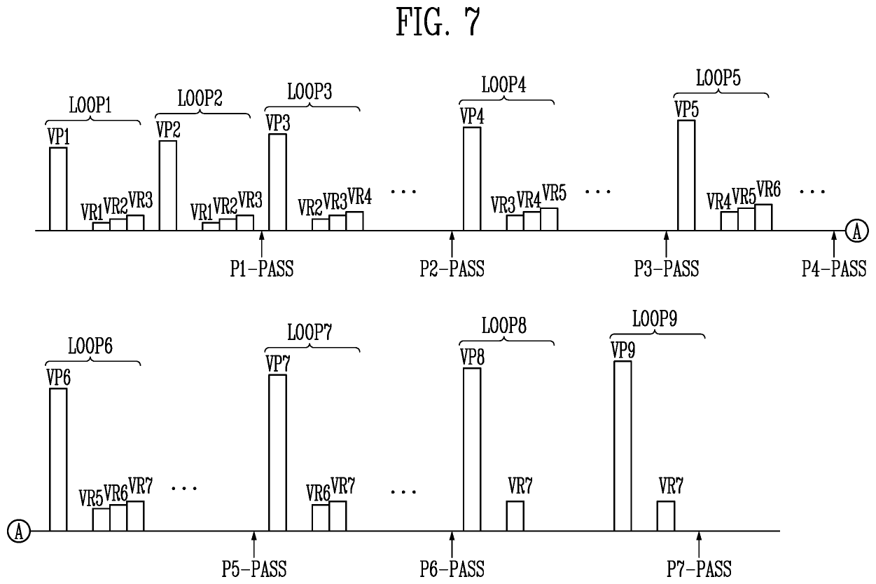

FIG. 7 is a diagram illustrating a program operation according to an embodiment of the present disclosure.

In an embodiment of the present disclosure, programming the memory cells in a TLC method is described as an example.

The program operation according to an embodiment of the present disclosure is described with reference to FIGS. 6 and 7 as follows.

Referring to FIGS. 6 and 7, an embodiment in which the program operation for the first to seventh program states P1 to P7 is performed according to an embodiment of the present disclosure is shown. In the program operation, a plurality of program loops LOOP1 to LOOP9 corresponding to the first to seventh program states P1 to P7 are sequentially performed. For example, the program loops LOOP1 and LOOP2 correspond to the first program state P1, and the program loop LOOP3 corresponds to the second program state P2. In addition, the program loop LOOP4 may correspond to the third program state P3, the program loop LOOP5 may correspond to the fourth program state P4, the program loop LOOP6 may correspond to the fifth program state P5, the program loop LOOP7 may correspond to the sixth program state P6, and the program loops LOOP8 and LOOP9 may correspond to the seventh program state P7.

Each of the plurality of program loops LOOP1 to LOOP9 may include the program voltage apply operation, the detrap operation, and at least one program verify operation. For example, during the program voltage apply operation in the program loop LOOP1, a program voltage VP1 is applied to the selected word line. Thereafter, the detrap operation of applying the set voltage to the source line is performed, and the program verify operation of applying the verify voltages VR1, VR2, and VR3 to the selected word line is performed.

As a result of the program verify operation included in each program loop, when a program of memory cells to be programmed to a program state corresponding to the program loop is completed by a set number or more, it is determined as a program pass, and a program loop for a next program state may be performed. For example, when it is determined that the program operation for the first program state P1 is passed as the result of the program verify operation of the program loop LOOP2 (P1-PASS), the program loop LOOP3 for the next program state (for example, the second program state) may be performed.

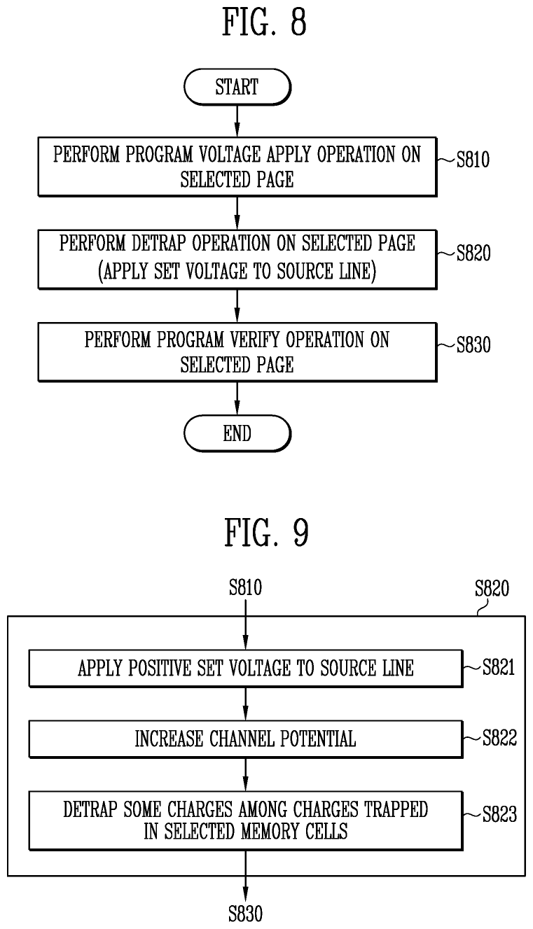

FIGS. 8 and 9 are flowcharts illustrating a program operation according to an embodiment of the present disclosure.

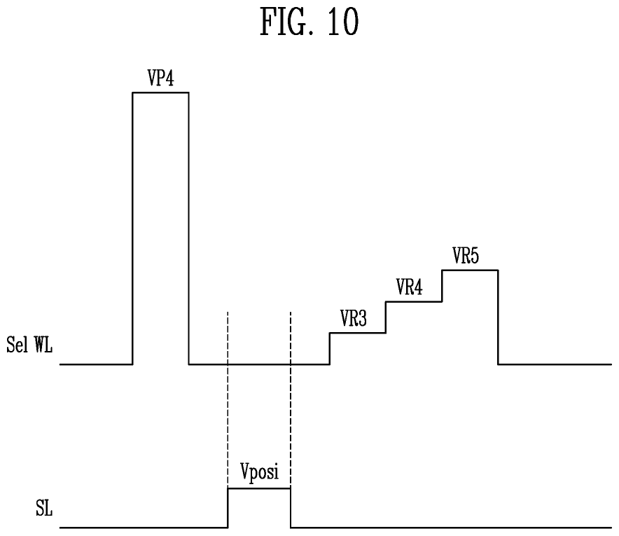

FIG. 10 is a diagram illustrating one program loop among the plurality of program loops of FIG. 7 according to an embodiment of the present disclosure.

A program operation method according to an embodiment of the present disclosure is described with reference to FIGS. 1, 5, and 8 to 10 as follows.

In an embodiment of the present disclosure, the program loop LOOP4 of the plurality of program loops LOOP1 to LOOP9 shown in FIG. 7 is described as an example.

The page buffers PB1 to PBm temporarily store data to be programmed during the program operation and adjust the potential levels of the bit lines BL1 to BLm based on the temporarily stored data to be programmed. For example, bit lines on which the program operation is to be performed are controlled to a program permission voltage level, and bit lines on which the program operation is not to be performed are controlled to a program inhibition voltage level.

In operation S810, the control logic 130 controls the peripheral circuits 120 to perform the program voltage apply operation on the selected page of the selected memory block. For example, the voltage generation circuit 121 generates a program voltage VP4 and the pass voltage in response to the operation signal OP_CMD, and the row decoder 122 applies the program voltage VP4 to the selected word line (for example, WL1) of the selected memory block (for example, BLK3) and applies the pass voltage to the remaining unselected word lines (for example, WL2 to WLn). Therefore, charges are trapped in the charge storage layer of the memory cells in which the corresponding bit line among the memory cells MC1 included in the selected page is controlled to the program permission voltage level.

In operation S820, the control logic 130 controls the peripheral circuits 120 to perform the detrap operation on the selected page of the selected memory block.

This is described in more detail as follows.

In operation S821, the source line driver 127 applies a positive set voltage Vposi to the source line SL of the selected memory block BLK3.

In operation S822, the channel potential of the plurality of cell strings CS1 to CSm included in the selected memory block BLK3 is increased by the positive set voltage Vposi applied to the source line SL. For example, the channel potential of the plurality of cell strings CS1 to CSm included in the selected memory block BLK3 is increased by turning on the source select transistors SST of the selected memory block BLK3. In another embodiment, the channel potential of the plurality of cell strings CS1 to CSm may be increased in a gate induced drain leakage (GIDL) method by applying a voltage of 0V to the gates of the source select transistors SST of the selected memory block BLK3.

In operation S823, among the charges trapped in the memory cells MC1 included in the selected page of the selected memory block BLK3, charges in an unstable state are detrapped by the increased channel potential. At this time, a voltage of 0V may be applied to the selected word line WL1 of the selected memory block BLK3, and the pass voltage may be applied to the unselected word lines WL1 to WLn.

In operation S830, the control logic 130 controls the peripheral circuits 120 to perform the program verify operation on the selected page of the selected memory block. For example, the voltage generation circuit 121 generates the verify voltage VR3 and the pass voltage in response to the operation signal OP_CMD, and the row decoder 122 applies the verify voltage VR3 to the selected word line (for example, WL1) of the selected memory block (for example, BLK3) and applies the pass voltage to the remaining unselected word lines (for example, WL2 to WLn). The page buffers PB1 to PBm sense the voltage or the current of the bit lines BL1 to BLm to perform the verify operation corresponding to the third program state P3. Thereafter, the voltage generation circuit 121 generates the verify voltage VR4 and the pass voltage, and the row decoder 122 applies the verify voltage VR4 to the selected word line (for example, WL1) of the selected memory block (for example, BLK3) and applies the pass voltage to the remaining unselected word lines (for example, WL2 to WLn). The page buffers PB1 to PBm sense the voltage or the current of the bit lines BL1 to BLm to perform the verify operation corresponding to the fourth program state P4. Thereafter, the voltage generation circuit 121 generates the verify voltage VR5 and the pass voltage, and the row decoder 122 applies the verify voltage VR5 to the selected word line (for example, WL1) of the selected memory block (for example, BLK3) and applies the pass voltage to the remaining unselected word lines (for example, WL2 to WLn). The page buffers PB1 to PBm sense the voltage or the current of the bit lines BL1 to BLm to perform the verify operation corresponding to the fifth program state P5.

As described above, in an embodiment of the present disclosure, the detrap operation may be performed between the program voltage apply operation and the program verify operation in the plurality of program loops included in the program operation, and the detrap operation may be performed by applying the positive set voltage to the source line SL of the selected memory block.

In addition, in the above-described embodiment, the detrap operation is performed in each program loop, but in order to improve a program operation speed, the detrap operation may be controlled to be performed only in some program loops and the program voltage apply operation and the program verify operation may be controlled to be performed in the remaining program loops. For example, during the program operation of the TLC method of programming memory cells to the first to seventh program states P1 to P7, the detrap operation may be controlled to be performed only in the program loops corresponding to the third and fourth program states P3 and P4. For example, the detrap operation may be controlled to be performed only in even-numbered program loops among the plurality of program loops.

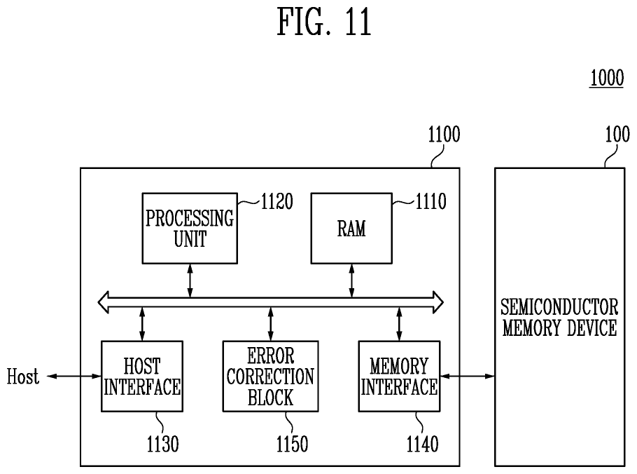

FIG. 11 is a block diagram illustrating a memory system 1000 including the semiconductor memory device of FIG. 1 according to an embodiment of the present disclosure.

Referring to FIG. 11, the memory system 1000 includes the semiconductor memory device 100 and a controller 1100. The semiconductor memory device 100 may be the semiconductor memory device described with reference to FIG. 1. Hereinafter, a repetitive description is omitted.

The controller 1100 is connected to a host Host and the semiconductor memory device 100. The controller 1100 is configured to access the semiconductor memory device 100 in response to a request from the host Host. For example, the controller 1100 is configured to control read, write, erase, and background operations of the semiconductor memory device 100. The controller 1100 is configured to provide an interface between the semiconductor memory device 100 and the host Host. The controller 1100 is configured to drive/execute instructions (e.g., firmware) for controlling the semiconductor memory device 100.

The controller 1100 includes a random access memory (RAM) 1110, a processing unit 1120, a host interface 1130, a memory interface 1140, and an error correction block 1150. The RAM 1110 is used as at least one of an operation memory of the processing unit 1120, a cache memory between the semiconductor memory device 100 and the host Host, and a buffer memory between the semiconductor memory device 100 and the host Host. The processing unit 1120 controls an overall operation of the controller 1100. In addition, the controller 1100 may temporarily store program data provided from the host Host during the program operation.

The host interface 1130 includes a protocol for performing data exchange between the host Host and the controller 1100. In an embodiment, the controller 1100 is configured to communicate with the host Host through at least one of various interface protocols such as a universal serial bus (USB) protocol, a multimedia card (MMC) protocol, a peripheral component interconnection (PCI) protocol, a PCI-express (PCI-E) protocol, an advanced technology attachment (ATA) protocol, a serial ATA protocol, a parallel ATA protocol, a small computer system interface (SCSI) protocol, an enhanced small disk interface (ESDI) protocol, an integrated drive electronics (IDE) protocol, and a private protocol.

The memory interface 1140 interfaces with the semiconductor memory device 100. For example, the memory interface 1240 includes a NAND interface or a NOR interface.

The error correction block 1150 is configured to detect and correct an error of data received from the semiconductor memory device 100 using an error correcting code (ECC). The processing unit 1120 may control the semiconductor memory device 100 to adjust a read voltage and perform re-read according to an error detection result of the error correction block 1150. In an embodiment, the error correction block may be provided as a component of the controller 1100.

The controller 1100 and the semiconductor memory device 100 may be integrated into one semiconductor device. In an embodiment, the controller 1100 and the semiconductor memory device 100 may be integrated into one semiconductor device to form a memory card. For example, the controller 1100 and the semiconductor memory device 100 may be integrated into one semiconductor device to form a memory card such as a PC card (personal computer memory card international association (PCMCIA)), a compact flash card (CF), a smart media card (SM or SMC), a memory stick, a multimedia card (MMC, RS-MMC, or MMCmicro), an SD card (SD, miniSD, microSD, or SDHC), and a universal flash storage (UFS).

The controller 1100 and the semiconductor memory device 100 may be integrated into one semiconductor device to form a semiconductor drive (solid state drive (SSD)). The semiconductor drive (SSD) includes a storage device configured to store data in a semiconductor memory. When the memory system 1000 is used as the semiconductor drive (SSD), an operation speed of the host connected to the memory system 1000 is dramatically improved.

In another example, the memory system 1000 is provided as one of various components of an electronic device such as a computer, an ultra-mobile PC (UMPC), a workstation, a net-book, a personal digital assistants (PDA), a portable computer, a web tablet, a wireless phone, a mobile phone, a smart phone, an e-book, a portable multimedia player (PMP), a portable game machine, a navigation device, a black box, a digital camera, a 3-dimensional television, a digital audio recorder, a digital audio player, a digital picture recorder, a digital picture player, a digital video recorder, a digital video player, a device capable of transmitting and receiving information in a wireless environment, one of various electronic devices configuring a home network, one of various electronic devices configuring a computer network, one of various electronic devices configuring a telematics network, an RFID device, or one of various components configuring a computing system.

In an embodiment, the semiconductor memory device 100 or the memory system 1000 may be mounted as a package of various types. For example, the semiconductor memory device 1300 or the memory system 1000 may be packaged and mounted in a method such as a package on package (PoP), ball grid arrays (BGAs), chip scale packages (CSPs), plastic leaded chip carriers (PLCC), a plastic dual in line package (PDIP), a die in waffle pack, die in wafer form, a chip on board (COB), a ceramic dual in line package (CERDIP), a plastic metric quad flat pack (MQFP), a thin quad flat pack (TQFP), a small outline integrated circuit (SOIC), a shrink small outline package (SSOP), a thin small outline package (TSOP), a system in package (SIP), a multi-chip package (MCP), a wafer-level fabricated package (WFP), or a wafer-level processed stack package (WSP).

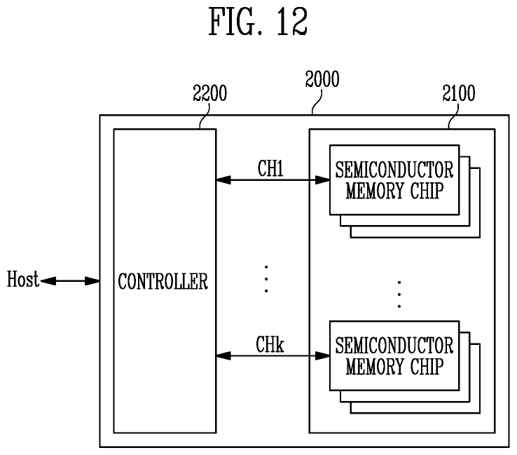

FIG. 12 is a block diagram illustrating an application example of the memory system of FIG. 11 according to an embodiment of the present disclosure.

Referring to FIG. 12, the memory system 2000 includes a semiconductor memory device 2100 and a controller 2200. The semiconductor memory device 2100 includes a plurality of semiconductor memory chips. The plurality of semiconductor memory chips are divided into a plurality of groups.

In FIG. 12, the plurality of groups communicate with the controller 2200 through first to k-th channels CH1 to CHk, respectively. Each semiconductor memory chip is configured and is operated similarly to that of the semiconductor memory device 100 described with reference to FIG. 1.

Each group is configured to communicate with the controller 2200 through one common channel. The controller 2200 is configured similarly to the controller 1100 described with reference to FIG. 11 and is configured to control the plurality of memory chips of the semiconductor memory device 2100 through the plurality of channels CH1 to CHk.

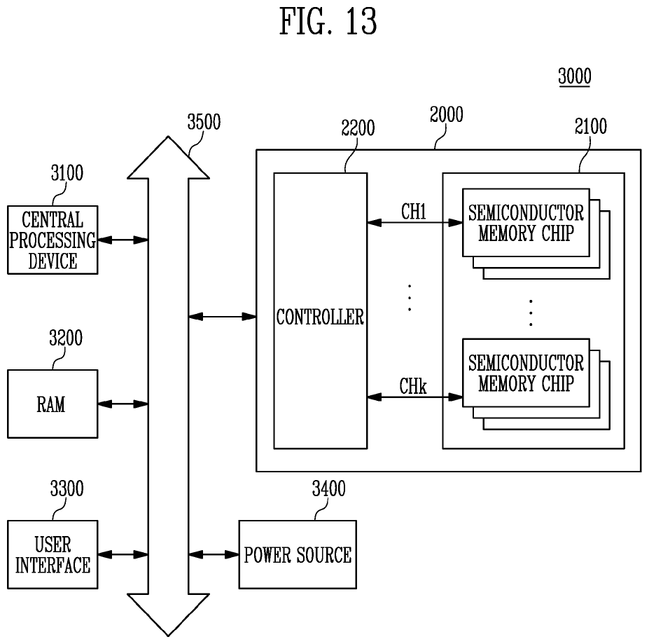

FIG. 13 is a block diagram illustrating a computing system including the memory system described with reference to FIG. 12 according to an embodiment of the present disclosure.

The computing system 3000 includes a central processing device 3100, a random access memory (RAM) 3200, a user interface 3300, a power source 3400, a system bus 3500, and the memory system 2000.

The memory system 2000 is electrically connected to the central processing device 3100, the RAM 3200, the user interface 3300, and the power source 3400 through the system bus 3500. Data provided through the user interface 3300 or processed by the central processing device 3100 is stored in the memory system 2000.

In FIG. 13, the semiconductor memory device 2100 is connected to the system bus 3500 through the controller 2200. However, the semiconductor memory device 2100 may be configured to be directly connected to the system bus 3500. At this time, a function of the controller 2200 is performed by the central processing device 3100 and the RAM 3200.

In FIG. 13, the memory system 2000 described with reference to FIG. 12 is provided. However, the memory system 2000 may be replaced with the memory system 1000 described with reference to FIG. 11. In an embodiment, the computing system 3000 may be configured to include both of the memory systems 1000 and 2000 described with reference to FIGS. 11 and 12.

The embodiments of the present disclosure disclosed in the present specification and drawings are merely specific examples for easily describing the technical content of the present disclosure and facilitating understanding of the present disclosure and do not limit the scope of the present disclosure. It is apparent to a person skilled in the art to which the present disclosure pertains that other modifications based on the technical spirit of the present disclosure may be carried out in addition to the embodiments disclosed herein. The scope of the present disclosure is defined by the claims to be described below rather than the detailed description, and it should be construed that the meaning and scope of the claims and all changes or modified forms derived from the equivalent concept thereof are included in the scope of the present disclosure.

What is claimed is:

1. A semiconductor memory device comprising:
a memory cell array including a plurality of memory blocks;
peripheral circuits for performing a program operation on a selected memory block among the plurality of memory blocks; and
a control logic for controlling the peripheral circuits to perform a detrap operation between a program voltage apply operation and a program verify operation during the program operation,
wherein the peripheral circuits apply a positive set voltage to a source line connected to the selected memory block during the detrap operation.

2. The semiconductor memory device of claim 1, wherein the peripheral circuits comprise:
a voltage generation circuit for generating a program voltage to be applied to a selected word line of the selected memory block;
a page buffer group for controlling a potential of bit lines of the selected memory block or sensing a potential or a current amount of the bit lines; and
a source line driver for applying the positive set voltage to the source line.

3. The semiconductor memory device of claim 1,
wherein each of the plurality of memory blocks includes a plurality of cell strings, and
wherein a potential of a channel of the plurality of cell strings of the selected memory block increases by the positive set voltage during the detrap operation.

4. The semiconductor memory device of claim 3, wherein the peripheral circuits apply a turn-on voltage to source select transistors of the selected memory block to control the positive set voltage to be applied to the channel during the detrap operation.

5. The semiconductor memory device of claim 3, wherein the peripheral circuits apply a voltage of 0V to source select transistors of the selected memory block to increase the potential of the channel in a gate induced drain leakage (GIDL) method during the detrap operation.

6. The semiconductor memory device of claim 1, wherein the peripheral circuits apply a voltage of 0V to a selected word line of the selected memory block during the detrap operation.

7. The semiconductor memory device of claim 1, wherein the peripheral circuits apply a pass voltage to unselected word lines of the selected memory block during the detrap operation.

8. A semiconductor memory device comprising:
a memory block including memory cells to be programmed to a plurality of program states;
peripheral circuits for performing a program operation on the memory block; and
a control logic for controlling the peripheral circuits to perform the program operation,
wherein the control logic controls the peripheral circuits to sequentially perform a program voltage apply operation, a detrap operation, and a program verify operation during the program operation for some of the plurality of program states.

9. The semiconductor memory device of claim 8, wherein the peripheral circuits apply a positive set voltage to a source line of the memory block during the detrap operation.

10. The semiconductor memory device of claim 9, wherein the peripheral circuits comprise:
a voltage generation circuit for generating a program voltage to be applied to a selected word line of the selected memory block;
a page buffer group for controlling a potential of bit lines of the selected memory block or sensing a potential or a current amount of the bit lines; and
a source line driver for applying the positive set voltage to the source line.

11. The semiconductor memory device of claim 9,
wherein the memory block includes a plurality of cell strings, and
wherein a potential of a channel of the plurality of cell strings increases by the positive set voltage during the detrap operation.

12. The semiconductor memory device of claim 11, wherein the peripheral circuits apply a turn-on voltage to source select transistors of the memory block to control the positive set voltage to be applied to the channel during the detrap operation.

13. The semiconductor memory device of claim 11, wherein the peripheral circuits apply a voltage of 0V to source select transistors of the memory block to increase the potential of the channel in a gate induced drain leakage (GIDL) method during the detrap operation.

14. The semiconductor memory device of claim 8, wherein the peripheral circuits apply a voltage of 0V to a selected word line of the memory block during the detrap operation.

15. The semiconductor memory device of claim 1, wherein the peripheral circuits apply a pass voltage to unselected word lines of the memory block during the detrap operation.

16. A method of operating a semiconductor memory device, the method comprising:
performing a program voltage apply operation of applying a program voltage to a selected word line among a plurality of word lines connected to a cell string including a plurality of memory cells to be programmed to a plurality of program states;
performing a detrap operation of applying a positive set voltage to a source line connected to the cell string after performing the program voltage apply operation; and
performing a program verify operation of applying a program verify voltage to the selected word line and sensing a voltage or a current of a bit line connected to the cell string, after performing the detrap operation.

17. The method of claim 16, wherein the performing of the detrap operation further includes applying a voltage of 0V the selected word line.

18. The method of claim 16, wherein the performing of the detrap operation further includes applying a pass voltage to a remaining unselected word line other than the selected word line.

19. The method of claim 16, wherein the performing of the detrap operation further includes applying a turn-on voltage to a source select transistor of the cell string to increase a channel potential of the cell string by the positive set voltage.

20. The method of claim 16, wherein the performing of the detrap operation further includes applying a voltage of 0V to a source select transistor of the cell string to increase a channel potential of the cell string in a gate induced drain leakage (GIDL) method.
